(19) United States
(12) Patent Application Publication
(10) Pub. No.: US 2006/0226419 A1
(43) Pub. Date: Oct. 12, 2006

(54) Encapsulation for an organic electronics component and production method therefor

(76) Inventors: Jan Birnstock, Dresden (DE); Debora Henseler, Erlangen (DE); Karsten Heurser, Erlangen (DE); Ralph Patzold, Roth (DE); Georg Wittmann, Herzgenaurach (DE)

Correspondence Address: YOUNG & THOMPSON, 745 SOUTH 23RD STREET, 2ND FLOOR, ARLINGTON, VA, 22202, US

(21) Appl. No.: 10/542,978

(22) PCT Filed: Jan. 20, 2004
(86) PCT No.: PCT/EP04/00429

§ 371 Date: Apr. 24, 2006

(30) Foreign Application Priority Data
Jan. 21, 2003 (DE) 103 02 145.0

(51) Int. Cl. H01L 29/08

(52) U.S. Cl. 257/40

(57) ABSTRACT

The invention relates to an encapsulation for an organic electronics component, particularly an OLED, which can be produced by simple coating methods or printing methods and which still has a high degree of tightness with regard to environmental influences that are detrimental to the organic electronics component. This is made possible by the use of so-called fusible alloys, i.e., low-melting point metallic alloys that combine a low melting point with a high tightness from moisture and oxidizing gases.

The invention relates to an encapsulation for an organic electronics component, in particular an encapsulation for an organic light emitting diode (OLED).

Displays which are based on OLEDs have been known since 1987. The OLEDs offer certain advantages compared with the conventional liquid crystal displays, namely auto emission, lower power consumption, compactness and short switching times.

An OLED is principally constructed from organic films which are arranged between two electrodes. Once voltage is applied to the electrodes, light is emitted because holes recombine with electrons. The thin organic layers of the OLED are typically arranged on a glass substrate and are encapsulated using a further glass or metal plate. In efforts to manufacture flexible organic displays, attempts are also being made to replace the rigid glass or metal plates with plates made of plastic. Nevertheless, a hermetic separation of the inner layers of an OLED from moisture and oxygen is essential, thus it is not easy to find a replacement for the materials glass or metal.

Several encapsulation techniques are currently being deployed, in which plastic encapsulation is used with an applied protection layer. Plastic layers made of dielectric layers are also used, having a thickness of up to 1 μm. However, these encapsulations are not necessarily to be classified as flexible.

An essential point in all encapsulations is to provide a tight seal against moisture, in particular water and oxidizing gases, in particular oxygen. Organic materials generally have a relatively high transparency for moisture, whereas metals and technical ceramics provide a good seal against these environmental influences, however it is difficult firstly to draw a metal film across an organic electronics component without damaging the component itself and secondly, conventional metal layers which were applied using CVD or similar methods have a relatively high number of ‘pinholes’ through which moisture and oxygen can diffuse.

It is the object of the present invention to create an encapsulation tightly sealed against moisture and oxidizing gases for an organic electronics component, in particular an OLED, which can be applied under normal processing conditions and which is flexible so that it is suitable for flexible applications.

The invention addresses the issue of an encapsulation for an electronics component, in particular for an OLED, which essentially can be manufactured from the molten mass of a metallic alloy. Furthermore the invention addresses a method for manufacturing an encapsulation for an OLED by applying the molten mass of a metallic alloy.

The phrase ‘essentially’ made from a metallic alloy indicates that the alloy can also have (conventional) additives, such as wetting agents, adhesive agents or the like added to it.

By way of example, the so-called low melting point alloys are the ‘fusible alloys’, in other words metallic alloys which have a low melting point or range of melting temperatures.

These materials allow hermetically tightly-sealed encapsulations for organic electronics components, in particular OLEDs, to be achieved by means of conventional coating methods such as pressure methods, ‘doctor-blading’, ‘spring coating’, or ‘dip-coating’, because the low melting point metallic alloys, the ‘fusible alloys’ which can be melted at temperatures between 30 and 200° C. can thus be processed like polymers. It is thus possible to manufacture a homogenous and broad surface coating as well as a structured layer.

According to a preferred exemplary embodiment of the method, the molten mass, preferably structured, is applied by means of a pressure process such as a stamp or pad printing, screen printing, ink jet printing, letter press and/or gravure printing, stencil printing, flexoprinting and the like.

According to a further embodiment of the method, the alloy of the ‘fusible alloys’ is applied by means of an embossing technique or like a casting resin.

The molten mass can be applied just as easily by means of spin coating, dipping, or a squeegee method.

The ‘fusible alloys’ are known according to their type, they are alloys for example which form an eutectic, in other words with a specific mole distribution, weight or volume distribution of the components by percentage in the alloys, the molten mass of the alloys or compound drops far below that of the individual components. The eutectic alloys are also advantageous in that they have a defined melting point in comparison with a range of melting temperatures, which can possibly cover 10° C. or more.

This is preferably an alloy which is present in the region between 30° C. and 200° C., in particular preferably below 150° C.

Elements of these alloys can be the following metals, bismuth, lead, tin, cadmium, indium, mercury, silver in which the ‘fusible alloy’ is characterized in that its melting point clearly lies below that of the individual elements, said melting point being measurable in degrees Celsius.

The ‘fusible alloys’ which pose no health risk are particularly advantageous, in other words those without or with only a small amount of cadmium, mercury and/or lead. The following alloys are worth mentioning by way of example, 57% (percent by weight) bismuth, 17% tin, 26% indium (melting point 78° C.), 48% tin, 52% indium (melting point 118° C.) or 58% bismuth, 42% tin (melting point 138° C.).

A great advantage of the method is furthermore that these materials generate a homogenous film with a low defect rate in comparison with films which were manufactured using physical vapor deposition (PVD) or CVD. Conventional encapsulations which were manufactured using CVD/PVD have a high defect rate or many ‘pin holes’ which is principle reason for deficient tightness of metallic/ceramic encapsulations.

Thin films can be manufactured using the method according to the invention for producing encapsulations, said films demonstrating a flexibility suited to flexible applications.

According to an embodiment, because the low melting point metallic alloys are electrically conductive, an insulation layer is applied between the organic electronics component, in particular between the OLED and the encapsulation. The insulating intermediate layer can for example be an organic layer or a ceramic layer, such as a layer of SiO₂. The intermediate insulation layer can be applied by means of vaporization, sputtering technique, chemical vapor deposition (CVD), ‘spin coating’ or by means of printing technology.

According to one exemplary embodiment of the method the molten mass is directly applied to the organic electronics component, in particular the OLED, so that it solidifies on the electronics component, advantageously in a controlled manner. This allows imperfections and pinholes to be prevented as much as possible. Only the fact that the mass melts at a range of low temperatures enables this method to be used for organic electronics components without damaging the component.

This form of encapsulation is particularly suitable for flexible applications (with plastic films or thin glass), because the solidified alloys, i.e. ‘fusible alloys’ present in a permanent phase, which are preferably present in the layer thickness in the encapsulation, are flexible.

The layer thicknesses of the encapsulations can lie between 1 and 700 μm. The preferred layer thicknesses are between 20 and 200 μm, with layer thicknesses of between 30 and 70 μm being especially preferred.

The adhesion characteristics of the alloys on the substrate such as glass and/or organic films are very advantageous, so that is also relatively easy to form a tight seal between the transition from encapsulation to substrate.

The encapsulation can be used for all organic electronics components, in particular for passive matrix displays, flexible light sources and or organic solar cells or organic photovoltaic cells. Further applications are flexible organic detectors and integrated circuits on an organic base.

By way of example, the encapsulation of an organic electronics component such as a passive matrix display, a solar cell or a flexible light source is described.

An organic electronics component is built up on a glass substrate. An insulating intermediate layer is applied by means of a coating method such as ‘spin coating’ or the like. A thin film, with a thickness of 50 μm for example, is in turn applied to a metallic low melting point alloy, by way of example 48% tin and 52% indium. The layers can be applied by means of simple printing technology, due to the low melting point of the alloy.

This invention proposes for the first time an encapsulation of an organic electronics component, in particular an OLED, which can be produced by simple coating methods or printing methods and nevertheless provides a very tight seal against environmental influences that are detrimental to the organic electronics component. This is made possible by the use of so-called fusible alloys, i.e. low-melting point metallic alloys that combine a low melting point with the ability to provide a very tight seal against moisture and oxidizing gases.

1. Encapsulation for an organic electronics component which is essentially manufactured from a molten mass of a metallic alloy.

2. Encapsulation according to claim 1, in which the alloy is present as a molten mass in a temperature range of 30 to 200° C.

3. Encapsulation according to claim 1, in which the metallic alloy in a solidified form, provides a tight seal against moisture and/or oxidizing gases.

4. Encapsulation according to claim 1, in which the alloy comprises at least one metal, selected from the following group of metals: Cadmium, tin, bismuth, lead, indium, mercury and/or silver.

5. Encapsulation according to claim 1, in which the thickness of the encapsulation layer amounts to between 1 and 700 μm.

6. Method for encapsulating an electronics component by applying the molten mass of a metallic alloy

7. Method according to claim 6, in which the molten mass is applied by means of a printing process.

8. Method according to claim 6, in which the molten mass solidifies on the organic electronics component.

9. Method according to claim 6, in which an insulating intermediate layer is applied to the organic electronics component prior to encapsulation.
